(19) United States
(12) Patent Application Publication
(10) Pub. No.: US 2025/0216431 A1
(43) Pub. Date: Jul. 3, 2025

(54) CAPACITANCE MEASUREMENT METHOD FOR A CAPACITIVE DEVICE

(71) Applicant: United Microelectronics Corp., Hsinchu (TW)

(72) Inventors: Pei Chieh Chiu, Tainan City (TW); Shang-Lin Ying, Tainan City (TW); Ching-Tsung Chen, Tainan City (TW); Cheng-Shu Yeh, Hsinchu City (TW); Kuang-Chuan Lee, Tainan City (TW); Shing-Ren Sheu, Hsinchu City (TW)

(73) Assignee: United Microelectronics Corp., Hsinchu (TW)

(21) Appl. No.: 18/432,073

(22) Filed: Feb. 5, 2024

(30) Foreign Application Priority Data
Dec. 28, 2023 (TW) 112151450

(51) Int. Cl. G01R 27/26; G01R 1/073; G01R 35/00

(52) U.S. Cl. CPC G01R 27/2605; G01R 1/07342; G01R 35/005

(57) ABSTRACT

A capacitance measurement method for a capacitive device is provided. The method includes: providing a wafter, on which the capacitive device is formed, having a set of calibration test pads and a set of test pads; applying a test signal to the set of calibration test pads through a first test path to measure a first capacitance between two calibration test pads; applying the test signal to the set of test pads through a second test path to measure a second capacitance between two test pads; and obtaining a capacitance of the capacitive device by a difference between the first capacitance and the second capacitance.

### CROSS-REFERENCE TO RELATED APPLICATION

This application claims the priority benefit of Taiwanese Patent Application No. 112151450, filed on Dec. 28, 2023. The entirety of the above-mentioned patent application is hereby incorporated by reference herein and made a part of this specification.

### BACKGROUND

### Technical Field

The present disclosure relates to a measurement method of a semiconductor device, and in particular, to a capacitance measurement method for a capacitive device.

### Description of Related Art

FIG. 1 is a schematic diagram illustrating a method of measuring a capacitance of the state art. As shown in FIG. 1, a semiconductor device is formed on a wafer W (schematic), and a capacitive device 10 is formed in the semiconductor device. When the capacitance of the capacitive device 10 is to be measured, usually, a pair of test pads 12 and 14 connected to two electrodes of the capacitive device 10 is used to make contact with the probes of the probe card of the test machine. By such contact, test signals can be applied to the test pads 12 and 14 to measure the capacitance of the capacitive device 10.

However, in general, parasitic capacitors may exist between the test pads 12 and 14. Therefore, the capacitance measured in this way will deviate from the actual capacitance, and the capacitance of the capacitive device 10 may not be accurately measured.

Therefore, there is a need to develop an effective way to accurately measure the capacitance of capacitive device without increasing testing costs.

### SUMMARY

As described above, the present disclosure provides a method for measuring a capacitance of a capacitive device, which can accurately measure the capacitance of the capacitive device in an effective manner without increasing testing costs.

According to an embodiment of the present disclosure, a capacitance measurement method of a capacitive device is provided. This capacitance measurement method comprises: providing a wafer, wherein the wafer is formed with the capacitive device, and the wafer is provided with a set of calibration test pads and a set of test pads; applying a test signal to the set of correction test pads through a first test path to measure a first capacitance between two calibration test pads in the set of calibration test pads; applying the test signal to the set of test pads through a second test path to measure a second capacitance between two test pads in the set of test pads, wherein the capacitive device is coupled between the two test pads; and obtaining a capacitance of the capacitive device based on a difference between the first capacitance and the second capacitance.

According to an embodiment of the present disclosure, the capacitance measurement method further comprises: measuring a voltage value between the two calibration test pads and a current value flowing between the two calibration test pads based on the test signal, and calculating the first capacitance based on a time variation rate of the voltage value and the current value; and measuring a voltage value between the two test pads and a current value flowing between the two test pads based on the test signal, and calculating the second capacitance based on a time variation rate of the voltage value and the current value.

According to an embodiment of the present disclosure, in the capacitance measurement method, a connection line between a center point of a first calibration test pad of the two calibration test pads and a center point of a first test pad of the two test pads is a first connection line, a connection line between a center point of a second calibration test pad of the two calibration test pads and a center point of a second test pad of the two test pads is a second connection line, the first connection line and the second connection line are parallel with each other. In addition, a distance between the center point of the first calibration test pad of the two calibration test pads and the center point of the first test pad of the two test pads is equal to a distance between the center point of the second calibration of the two calibration test pads and the center point of the second test pad of the two test pads.

According to an embodiment of the present disclosure, in the capacitance measurement method, a distance between respective center points of the two calibration test pads in the set of calibration test pads is equal to a distance between respective center points of the two test pads in the set of test pads.

According to an embodiment of the present disclosure, in the capacitance measurement method, a size of each of the two calibration test pads in the set of calibration test pads is the same as a size of each of the two test pads in the set of test pads.

According to an embodiment of the present disclosure, in the capacitance measurement method, the capacitive device may be a deep trench capacitor.

According to another embodiment of the present disclosure, a capacitance measurement method for a capacitive device is provided. The capacitance measurement method comprises: providing a wafer, wherein the wafer is formed with the capacitive device, and the wafer is provided with a set of calibration test pads and a set of test pads; providing a test probe card, wherein a switch device is provided on the test probe card; applying a test signal to the set of calibration test pads by operating the switch device to make the test probe card be coupled to the set of calibration test pads, so as to measure a first capacitance between the two calibration test pads in the set of calibration test pads; applying the test signal to the set of test pads by operating the switch device to make the test probe card be coupled to the set of test pads, so as to measure a second capacitance between the two test pads in the set of test pads, wherein the capacitive device is coupled between the two test pads; obtaining a capacitance of the capacitive device based on a difference between the first capacitance and the second capacitance.

According to an embodiment of the present disclosure, the capacitance measurement method further comprises: measuring a voltage value between the two calibration test pads and a current value flowing between the two calibration test pads based on the test signal, and calculating the first capacitance based on a time variation rate of the voltage value and the current value; and measuring a voltage value between the two test pads and a current value flowing between the two test pads based on the test signal, and calculating the second capacitance based on a time variation rate of the voltage value and the current value.

According to an embodiment of the present disclosure, in the capacitance measurement method, a distance between respective center points of the two calibration test pads in the set of calibration test pads is equal to a distance between respective center points of the two test pads in the set of test pads.

According to an embodiment of the present disclosure, in the capacitance measurement method, a size of each of the calibration test pads in the set of calibration test pads may be the same as a size of each of the test pads in the set of test pads.

According to an embodiment of the present disclosure, in the capacitance measurement method, providing the test probe card further comprises: providing a first set of test probes and a second set of test probes on the test probe card; switching to the first set of test probes by operating the switch device so that the first set of test probes is coupled to the set of calibration test pads; and switching to the second set of test probes by operating the switch device so that the second set of test probes is coupled to the set of test pads.

According to an embodiment of the present disclosure, in the capacitance measurement method, the switch device may be a relay switch or a transistor switch.

According to an embodiment of the present disclosure, in the capacitance measurement method, the capacitive device is a deep trench capacitor.

Based on the above, calibration test pads are added on the wafer (device under test) to provide two sets of test paths. By measuring the voltage and current of the calibrated test pads, the first capacitance value excluding the capacitive element (i.e., the parasitic capacitance between the calibrated test pads) is calculated. In addition, the voltage and current of the capacitive device of the wafer are measured to calculate the second capacitance value. From this, the capacitance value of the capacitive device without the parasitic capacitance between the test pads can be calculated to improve the accuracy of capacitance measurement.

### BRIEF DESCRIPTION OF THE DRAWINGS

FIG. 1 is a schematic diagram illustrating a method of measuring capacitance of the state art.

FIG. 2 is a schematic diagram illustrating the capacitance measurement according to an embodiment of the present disclosure.

FIG. 3 is a schematic diagram illustrating a probe card according to an embodiment of the present disclosure.

FIG. 4 is a voltage-current curve based on the capacitance calculation method according to an embodiment of the present disclosure.

FIG. 5 is a flow chart for measuring a capacitance of a capacitive device according to an embodiment of the present disclosure.

FIG. 6 is a flow chart for measuring a capacitance of a capacitive device according to an embodiment of the present disclosure.

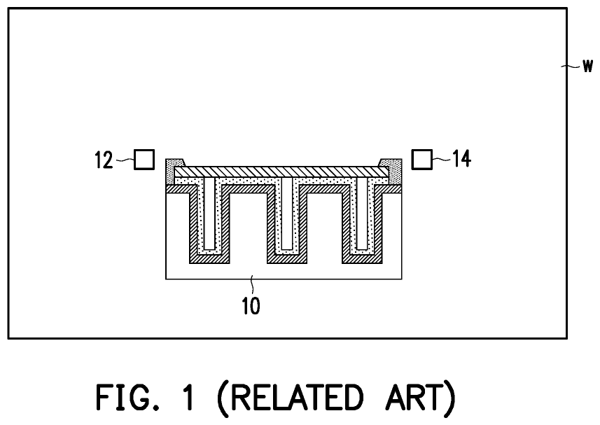

### DESCRIPTION OF THE EMBODIMENTS

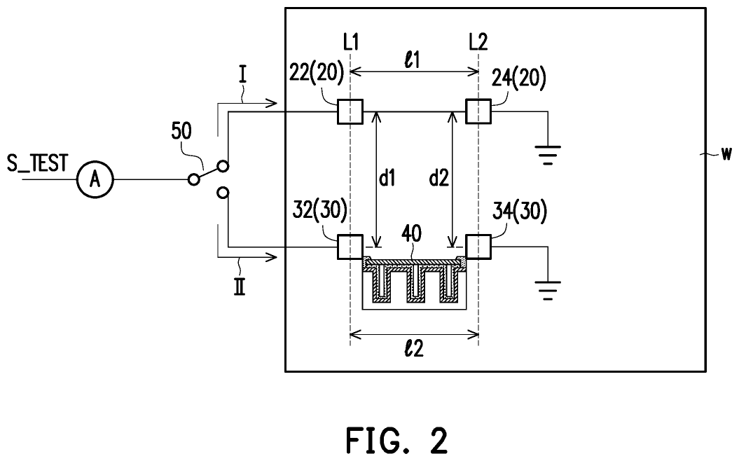

FIG. 2 is a schematic diagram illustrating capacitance measurement according to an embodiment of the present disclosure. As shown in FIG. 2, according to an embodiment of the present disclosure, a set of calibration test pads 20 and a set of test pads 30 are arranged on a wafer W. The set of calibration test pads 20 may comprise calibration test pads 22 and 24, or referring to a first calibration test pad 22 and a second calibration test pad 24. The calibration test pads 22 and 24 may receive the test signal S_TEST from the test machine. By applying the test signal S_TEST to the calibration test pads 22 and 24, the first capacitance C1 between the calibration test pads 22 and 24 can be calculated.

The set of test pads 30 may comprise test pads 32 and 34, or referring to a first test pad 32 and a second test pad 34. The test pads 32, 34 may be respectively coupled to a capacitive device 40 in a semiconductor device formed on the wafer W. As an example, the capacitive device 40 may be a deep trench capacitor (DTC), but the capacitive device 40 may be other types of capacitors, and the present disclosure is not particularly limited. For example, the test pads 32, 34 are respectively coupled to two electrodes (not shown) of the capacitive device 40. The test pads 32 and 34 may receive the test signal S_TEST from the test machine. By applying the test signal S_TEST to the test pads 32 and 34, a second capacitance C2 between the test pads 32 and 34 may be calculated.

In addition, according to the embodiment of the present disclosure, in order to make the set of calibration test pads facilitate the calibration, the distance I1 between the respective center points of the two calibration test pads 22 and 24 in the set of calibration test pads 20 is equal to the distance I2 between the respective center points of the two test pads 32 and 34 in the set of test pads 30. In addition, the size of each of the calibration test pads 22, 24 in the set of calibration test pads 20 is the same as the size of each of the test pads 32, 34 in the set of test pads 30. This configuration ensures that the electrical properties of the two sets of test pads are approximately the same.

In addition, when measuring the capacitance of the capacitive device 40, two test paths are provided, one of which is the first test path I and the other is the second test path II. Switching between the first test path I and the second test path II can be implemented through a switch device 50 provided on the test probe card. In addition, in order to make the set of calibration test pads facilitate the calibration, the positions of the calibration test pads 22, 24 on the first test path I and the positions of the test pads 32, 34 on the second test path II are designed to be aligned with each other at the corresponding location. As an example, the connection line between the center point of the calibration test pad 22 and the center point of the test pad 32 is defined as the first connection line L1, and the connection line between the center point of the calibration test pad 24 and the center point of the test pad 34 is defined as the second connection line L2. The first connection line L1 and the second connection line L2 are substantially parallel. Moreover, the distance d1 between the center point of the calibration test pad 22 and the center point of the test pad 32 is substantially equal to the distance d2 between the center point of the calibration test pad 24 and the center point of the test pad 34.

The test probe card and the switch device 50 will be described in further detail below.

According to the embodiment of the present disclosure, as shown in FIG. 2, first, the switch device 50 is operated to switch to the first test path I. At this time, the test signal S_TEST from the test machine (not shown) will be applied to the calibration test pads 22, 24 of the set of calibration test pads 20. When the test signal S_TEST is applied, the current value of a current passing through the electrical path formed by the calibration test pads 22, 24 and the voltage value between the calibration test pads 22, 24 may be measured. Therefore, the first capacitance C1 between the calibration test pads 22, 24 may be calculated based on the change of voltage values at two time points (i.e., time variation rate of the voltage value) and the current value. In addition, since there is no capacitive device to be measured between the calibration test pads 22, 24, the first capacitance C1 may be referred as a parasitic capacitance between the calibration test pads 22, 24.

Then, the switch device 50 is operated to switch to the second test path II. At this time, the test signal S_TEST from the test machine is applied to the test pads 32, 34 of the set of test pads 30. When the test signal S_TEST is applied, the current value of a current passing through the electrical path formed by the test pads 32, 34 and the voltage value between the test pads 32, 34 may be measured. Here, the electrical path passes through the capacitive device 40 mentioned above. Therefore, the second capacitance C2 between the test pads 32, 34 can be calculated based on the change of voltage values at two time points (i.e., time variation rate of the voltage value) and the current value.

At this time, the second capacitance C2 includes the capacitance C of the capacitive device 40 itself and the parasitic capacitance between the test pads 32 and 34. As mentioned above, the dimensions of the calibration test pads 22, 24 and the test pads 32, 34 and the distance between the test pads are the same. Therefore, the parasitic capacitance between the test pads 32, 34 is substantially equal to the parasitic capacitance between the calibration test pads 22, 24. Therefore, the capacitance of the capacitive device 40 may be calculated in the following manner.

Capacitance C=second capacitance C2−first capacitance C1

Therefore, by adding a set of calibration test pads 20 on the wafer W and measuring the capacitance of the two test paths respectively, the capacitance of the capacitive device 40 may be accurately calculated by taking the difference between the first capacitance C1 and the second capacitance C2, that is, the parasitic capacitance between test pads can be eliminated.

In addition, since the embodiment simply adds the calibration test pads on the wafer during the manufacturing process, it will not increase the cost of the manufacturing process, and it will not damage the integrity of the original manufacturing process. Therefore, accurate capacitance measurement may be performed with low cost. In addition, a switch device is added to the test probe card to switch the different test paths. Therefore, it is not necessary to modify the test machine. The cost of modifying the test probe card is also low, and thus the accurate capacitance measurement may be achieved with low cost.

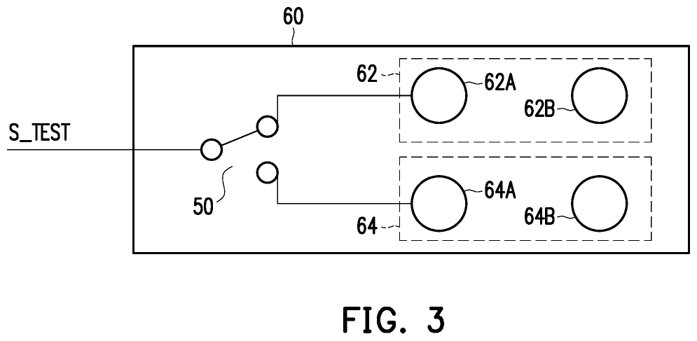

FIG. 3 is a schematic diagram illustrating a test probe card according to an embodiment of the present disclosure. As shown in FIG. 3, the test probe card 60 includes a first set of test probes 62, a second set of test probes 64 and a switch device 50. The first set of test probes 62 may include test probes 62A, 62B. The test probes 62A and 62B of the first set of test probes 62 are respectively used to make electrical contact with the calibration test pads 22, 24 shown in FIG. 2, so as to apply the test signal S_TEST to the calibration test pads 22, 24. Additionally, the second set of test probes 64 may include test probes 64A, 64B. The test probes 64A and 64B of the second set of test probes 64 are respectively used to make electrical contact with the test pads 32, 34 shown in FIG. 2, so as to apply the test signal S_TEST to the test pads 32 and 34.

As an example, the test probes 62A, 62B of the first set of test probes 62 are configured in a manner that substantially corresponds to the configuration of the calibration test pads 22, 24 shown in FIG. 2. The configuration of the test probes 64A and 64B of the second set of test probes 64 basically corresponds to the configuration of the calibration test pads 32 and 34 shown in FIG. 2. However, as long as the arrangement of the test probes 62A, 62B, 64A, and 64B shown in FIG. 3 may correspond to the calibration test pads 22, 24 and the test pads 32, 34 on the wafer W, the arrangement of the calibration test pads 22, 24 and the test pads 32, 34 may have variations.

In addition, the switch 50 is used to switch between the first set of test probes 62 and the second set of test probes 64. When the switch 50 switches to the first set of test probes 62, the first capacitance value C1 between the calibration test pads 22 and 24, that is, the parasitic capacitance between the test pads, can be measured. When the switch 50 switches to the second set of test probes 62, the second capacitance value C2 between the test pads 32 and 34 can be measured, that is, the capacitance value of the capacitive device 40 including the parasitic capacitance between the test pads.

In addition, the switch device 50 may be configured by a relay switch. The switch device 50 may also be configured by a transistor switch. Without affecting the implementation of the present disclosure, any switching element may be used to implement the switch device 50.

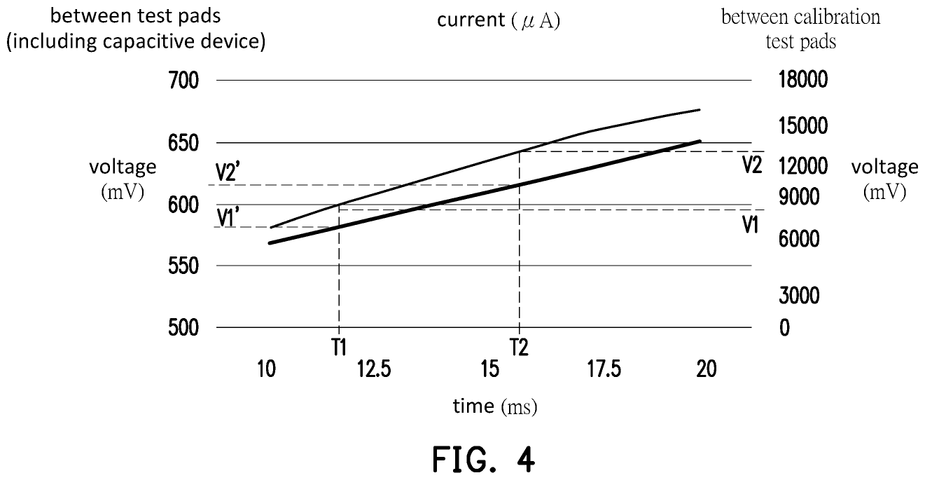

Next, the calculation method of the first capacitance C1 and the second capacitance C2 will be described. FIG. 4 is a voltage-current curve illustrating a calculation method of capacitance according to an embodiment of the present disclosure. FIG. 4 shows the relationship between the voltage and time measured with the two calibration test pads 22, 24 of the set of calibration test pad 20 for the first test path I and the relationship between the voltage and time measured with the two test pads 32, 34 of the set of test pad 30 for the second test path II under the same current (such as 100 μA). In addition, in FIG. 4, the vertical axis on the right side represents the voltage value V (mV) between the two calibration test pads 22, 24, the vertical axis on the left side represents the voltage value V (mV) between the two test pads 32, 34, and the horizontal axis represents time (ms). At this time, regarding the voltage value V between the calibration test pads 22, 24, the voltage value measured at time T1 is V1, and the voltage value measured at time T2 is V2. The first capacitance value C1 may be calculated by the following equation.

Q1=I1×Δt1, wherein Q1 is the charge of the capacitor.

C1=I1×Δt1/ΔV=I1×(T2−T1)/(V2−V1).

Thus, in this example, the calculated first capacitance C1, that is, the parasitic capacitance between the test pads is approximately 0.1 μF.

In addition, regarding the voltage value V between the test pads 32, 34, the measured voltage value at time T1 is V1′, and the measured voltage value at time T2 is V2′. The second capacitance C2 may be calculated by the following equation.

Q2=I2×Δt2, wherein Q is the charge of the capacitor.

C2=I2×Δt2/ΔV=I2×(T2−T1)/(V2−V1).

Thus, in this example, the calculated second capacitance C2, that is, the capacitance to be corrected (the capacitance including parasitic capacitance) of the capacitive device 40 between the test pads is approximately 10 μF.

Then, the first capacitance C1 can be used as the calibration value, and the first capacitance C1 equivalent to the parasitic capacitance value is subtracted from the second capacitance C2 to obtain the calibrated capacitance of the capacitive device 40.

As an example, the test machine that is operated with the test probe card 60 may comprises a hardware processor and a memory that is cooperated with the hardware processor. The hardware processor may be configured to provide the test signal S_TEST, and perform calculation to obtain the capacitance of the capacitive device 40 based on the measured data, such as the current values and the voltage values. In one example, these the current values and the voltage values may be stored in the memory.

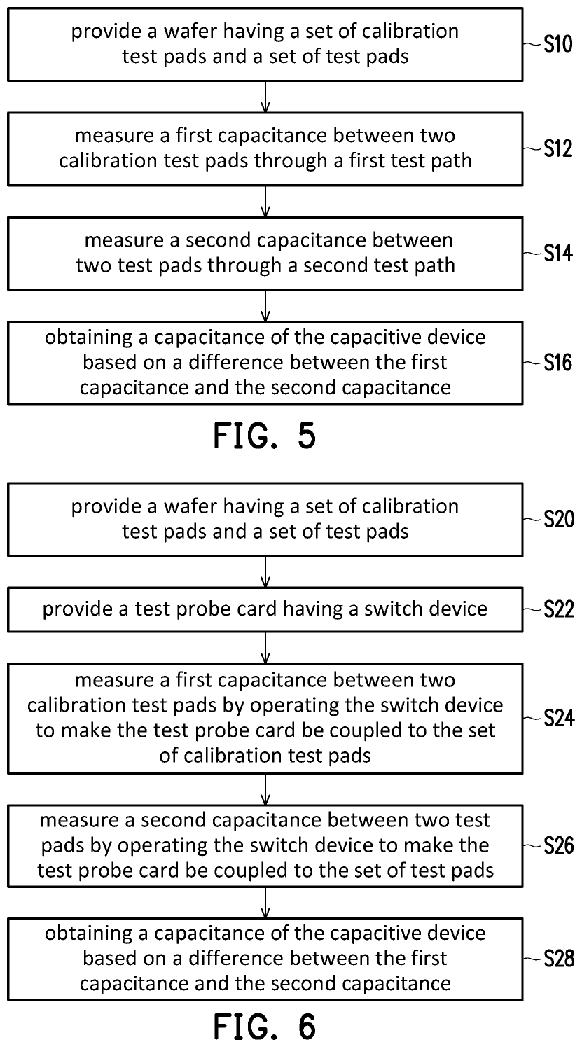

Next, a method for measuring the capacitance of the capacitive device according to the embodiment of the present disclosure will be described. FIG. 5 is a flow chart of measuring a capacitance of a capacitive device according to an embodiment of the present disclosure. As shown in FIG. 5 and FIG. 2, first, in step S10, a wafer W is provided, and the wafer W is formed with the capacitive device 40. The wafer W is provided with a set of calibration test pads 20 for measuring the capacitance between the calibration test pads 22, 24, and a set of test pads 30 for measuring the capacitance of the capacitive device 40.

In step S12, the test signal S_TEST is applied to the set of calibration test pads 20 through the first measurement path I to measure the first capacitance C1 between the two calibration test pads 22, 24 in the set of calibration test pads 20. Then, in step S14, the test signal S_TEST is applied to the set of test pads 30 through the second measurement path II to measure the second capacitance C2 between the two test pads 32 and 34 in the set of test pads 30.

In step S16, the difference between the first capacitance value C1 and the second capacitance value C2 is calculated to obtain the capacitance C2-C1 of the capacitive device 40. Therefore, an accurate capacitance of the capacitive device 40, which the parasitic capacitance between the test pads is eliminated, may be obtained.

FIG. 6 is a flow chart of measuring a capacitance of a capacitive device according to an embodiment of the present disclosure. As shown in FIG. 6 and FIG. 3, first, in step S20, a wafer W is provided, and the wafer W is formed with the capacitive device 40. The wafer W is provided with a set of calibration test pads 20 for measuring the capacitance between the calibration test pads 22, 24, and a set of test pads 30 for measuring the capacitance value of the capacitive device 40.

In step S22, the test probe card 60 is provided. The test probe card 60 is provided with a switch device 50. As shown in FIG. 3, the test probe card 60 further comprises a first set of test probes 62 and a second set of test probes 64.

In step S24, the first set of test probes 62 of the test probe card 60 is coupled to the set of calibration test pads 20 by operating the switch device 50 of the test probe card 60. In this manner, the test signal S_TEST is applied to the set of calibration test pads 20 through the first set of test probes 62 to measure the first capacitance C1 between the two calibration test pads 22, 24 in the set of calibration test pads 20.

In step S26, the second set of test probes 64 of the test probe card 60 is coupled to the set of test pads 30 by operating the switch device 50 of the test probe card 60. In this manner, the test signal S_TEST is applied to the set of test pads 30 through the second set of test probes 64 to measure the second capacitance C2 between the two test pads 32, 34 in the set of test pads 30.

In step S28, the difference between the first capacitance C1 and the second capacitance C2 is calculated to obtain the capacitance C2-C1 of the capacitive device 40. Thus, an accurate capacitance value of the capacitive device 40, which the parasitic capacitance between the test pads is eliminated, may be obtained.

In summary, based on the above description, according to the embodiment of the present disclosure, in addition to the normal test pads, the calibration test pads are added to the wafer (device under test) to provide two sets of test paths. By measuring the voltage and current of the calibrated test pads (first test path), the first capacitance that does not include the capacitance of the capacitive device (i.e., the parasitic capacitance between test pads) is calculated. In addition, by measuring voltage and current (second test path) for the capacitive device on the wafer, the second capacitance may be calculated. From this, the capacitance of the capacitive device without the parasitic capacitance between the test pads can be calculated, and therefore, the accuracy of capacitance measurement may be improved.

What is claimed is:

1. A capacitance measurement method for a capacitive device, comprising:
providing a wafer, wherein the wafer is formed with the capacitive device, and the wafer is provided with a set of calibration test pads and a set of test pads;
applying a test signal to the set of correction test pads through a first test path to measure a first capacitance between two calibration test pads in the set of calibration test pads;
applying the test signal to the set of test pads through a second test path to measure a second capacitance between two test pads in the set of test pads, wherein the capacitive device is coupled between the two test pads; and
obtaining a capacitance of the capacitive device based on a difference between the first capacitance and the second capacitance.

2. The capacitance measurement method according to claim 1, further comprising:
measuring a voltage value between the two calibration test pads and a current value flowing between the two calibration test pads based on the test signal, and calculating the first capacitance based on a time variation rate of the voltage value and the current value; and
measuring a voltage value between the two test pads and a current value flowing between the two test pads based on the test signal, and calculating the second capacitance based on a time variation rate of the voltage value and the current value.

3. The capacitance measurement method according to claim 1, wherein a connection line between a center point of a first calibration test pad of the two calibration test pads and a center point of a first test pad of the two test pads is a first connection line, a connection line between a center point of a second calibration test pad of the two calibration test pads and a center point of a second test pad of the two test pads is a second connection line, the first connection line and the second connection line are parallel with each other, and
a distance between the center point of the first calibration test pad of the two calibration test pads and the center point of the first test pad of the two test pads is equal to a distance between the center point of the second calibration of the two calibration test pads and the center point of the second test pad of the two test pads.

4. The capacitance measurement method according to claim 1, a distance between respective center points of the two calibration test pads in the set of calibration test pads is equal to a distance between respective center points of the two test pads in the set of test pads.

5. The capacitance measurement method according to claim 1, wherein a size of each of the two calibration test pads in the set of calibration test pads is the same as a size of each of the two test pads in the set of test pads.

6. The capacitance measurement method according to claim 1, wherein the capacitive device is a deep trench capacitor.

7. A capacitance measurement method for a capacitive device, comprising:
providing a wafer, wherein the wafer is formed with the capacitive device, and the wafer is provided with a set of calibration test pads and a set of test pads;
providing a test probe card, wherein a switch device is provided on the test probe card;
applying a test signal to the set of calibration test pads by operating the switch device to make the test probe card be coupled to the set of calibration test pads, so as to measure a first capacitance between the two calibration test pads in the set of calibration test pads;
applying the test signal to the set of test pads by operating the switch device to make the test probe card be coupled to the set of test pads, so as to measure a second capacitance between the two test pads in the set of test pads, wherein the capacitive device is coupled between the two test pads;
obtaining a capacitance of the capacitive device based on a difference between the first capacitance and the second capacitance.

8. The capacitance measurement method according to claim 7, further comprising:
measuring a voltage value between the two calibration test pads and a current value flowing between the two calibration test pads based on the test signal, and calculating the first capacitance based on a time variation rate of the voltage value and the current value; and
measuring a voltage value between the two test pads and a current value flowing between the two test pads based on the test signal, and calculating the second capacitance based on a time variation rate of the voltage value and the current value.

9. The capacitance measurement method according to claim 7, wherein a distance between respective center points of the two calibration test pads in the set of calibration test pads is equal to a distance between respective center points of the two test pads in the set of test pads.

10. The capacitance measurement method according to claim 7, wherein a size of each of the calibration test pads in the set of calibration test pads is the same as a size of each of the test pads in the set of test pads.

11. The capacitance measurement method according to claim 7, wherein providing the test probe card further comprises:
providing a first set of test probes and a second set of test probes on the test probe card;
switching to the first set of test probes by operating the switch device so that the first set of test probes is coupled to the set of calibration test pads; and
switching to the second set of test probes by operating the switch device so that the second set of test probes is coupled to the set of test pads.

12. The capacitance measurement method according to claim 7, wherein the switch device is a relay switch.

13. The capacitance measurement method according to claim 7, wherein the switch device is a transistor switch.

14. The capacitance measurement method according to claim 7, wherein the capacitive device is a deep trench capacitor.
